(19) United States
(12) Patent Application Publication
(10) Pub. No.: US 2007/0243492 A1
(43) Pub. Date: Oct. 18, 2007

(54) Double exposure photolithographic process

(76) Inventors: Peter J. McElheny, Morgan Hill, CA (US); Yowjuang (Bill) Liu, San Jose, CA (US)

Correspondence Address: MORGAN, LEWIS & BOCKIUS LLP, 1111 PENNSYLVANIA AVENUE, WASHINGTON, DC, 20004, US

(21) Appl. No.: 11/710,650

(22) Filed: Feb. 23, 2007

Related U.S. Application Data
(60) Provisional application No. 60/792,038, filed on Apr. 14, 2006.

(51) Int. Cl. G03F 7/26

(52) U.S. Cl. 430/316; 430/311; 430/313; 430/322; 430/323

(57) ABSTRACT

A first high resolution pattern is defined in a first layer of photoresist on a work surface and portions of the first layer are removed to expose the pattern on the work surface. The exposed portions of the work surface and the remaining portions of the first layer are then covered by a second layer of photoresist. A second lower resolution pattern is then defined in the second layer and portions of the second layer are removed to expose on the work surface a third pattern that is a subset of the first pattern. Standard (non-custom) masks may be used to define the first pattern while custom but lower resolution masks are used to define the second pattern.

### CROSS REFERENCE TO RELATED APPLICATIONS

The present application claims priority to U.S. Provisional Patent Application Ser. No. 60/792,038, filed Apr. 14, 2006.

### FIELD OF THE INVENTION

This relates to a double exposure photolithographic method. It is especially useful in the processing of work surfaces at extremely high resolution. It will be described in the context of processing metallization layers or vias formed on the surfaces of semiconductor substrates in integrated circuits; but it could be used in processing the substrate or other layers, such as poly-silicon, on the substrate.

### BACKGROUND OF THE INVENTION

Numerous types of integrated circuits (ICs) include standardized structures. These ICs are referred to as application specific integrated circuits (ASICs). These ASICs include standard cell ASICs which comprise a variety of circuits (or cells) selected from a library of pre-designed standard circuits and connected together in unique arrangements to form the entire ASIC, programmable logic devices (PLDs) which comprise arrays of logic elements that are selectively interconnected to achieve specific logic functions and field programmable gate arrays (FPGAs) which are standard circuits that can be interconnected by programmable switches. The connections between the cells in the standard-cell ASICs are formed in the metallization layers and vias of the ASICs and these connections are specified on the masks that are used to form these layers. As a result, each mask layer needs to be customized, resulting in long design cycles and substantial non-recurrent engineering (NRE) costs. At the other end of the design spectrum, the programmable switches that interconnect the circuits of an FPGA are controlled or configured by bits stored in a configurable memory that typically is part of the FPGA. As a result, the mask layers used to form an FPGA need no customization with the result that development is faster and there are no NRE costs. However, FPGAs typically have higher unit prices and higher power consumption than standard-cell ASICs that accomplish the same tasks. Further information about ASICs may be found in M. J. S. Smith, Application Specific Integrated Circuits (Addison-Wesley 1997).

A more recent development is another type of ASIC variously called a structured ASIC or structured array or platform ASIC. The structured ASIC provides faster development times and lower NRE costs than standard-cell ASICs and significantly lower unit cost and power and often higher performance than high-end FPGAs. Structured ASICs embed logic and hard functions such as memory, phase locked loops (PLL), clock networks and power bussing into pre-engineered, pre-verified base layers of metallization. Thus, the masks that define these layers are standard (i.e., non-custom) masks that are used in a wide variety of structured ASICs and the NRE costs associated with the design of these masks can be spread over a large number of devices. The structured ASIC is customized using just a few high resolution masks to define the critical metal layers. Typically these high resolution masks are used to define the smallest features that can be defined for the technology node at which they are used.

One type of structured ASIC is the HardCopy® structured ASIC supplied by the assignee, Altera Corporation. HardCopy® structured ASICs embed hard functions from Altera's Stratix® FPGA series (and equivalent I/O) into the base layers of the ASIC.

Structured ASICs such as Altera's HardCopy® ASIC have been successfully used to speed up development and lower NRE costs. One particularly advantageous design process has been to verify a design using 90 nm FPGAs for prototyping and then migrating the FPGA-verified design into structured ASICs. This design process is described in several papers by Ro Chawla that are available at the Altera web-site.

While this design process has worked well for designs using the 90 nm technology nodes, mask costs rise significantly as one moves to more advanced technology nodes such as the 65 nm technology node. In particular, the cost of the masks used for the custom metal layers of the 65 nm technology node is more than double the cost of such masks used for the custom metal layers of the 90 nm technology node.

### SUMMARY OF THE PRESENT INVENTION

The present invention is a method and apparatus for reducing mask costs in the manufacture of structured ASICs and the like. A pair of masks and some additional processing steps are used in place of a single high resolution mask and conventional processing.

In an illustrative embodiment of the invention, a first layer of photoresist is formed on a work surface such as a layer of metallization or dielectric. The photoresist is then exposed to actinic radiation in a pattern having features defined by a first mask. Preferably, the mask is an extremely high resolution mask and the features defined by the mask are in a regular array extending across the entire region of the photoresist where structures are to be formed.

Following the exposure step, portions of the photoresist are selectively removed so as to expose portions of the underlying work surface.

A second layer of photoresist is then formed on the first layer of photoresist and on the exposed pattern on the work surface. The second layer of photoresist is then exposed to actinic radiation in a second pattern having features defined by a second mask. Preferably, the second mask has a lower resolution than the first mask and as a result is considerably less expensive than the first mask. In addition, the lower resolution exposure may also be performed using radiation at a lower frequency than in the high resolution exposure and possibly using less expensive exposure equipment. The features defined by the second mask are aligned with the features defined by the first mask.

Following the exposure step, portions of the second layer of photoresist are selectively removed so as to expose portions of the underlying work surface. The portions of photoresist removed from the second layer are aligned with the regions of the first photoresist layer from which photoresist was removed in the previous removal step so that the removal of portions of the second photoresist layer exposes a third pattern on the work surface that is a subset of the first pattern previously exposed on the work surface.

Further, the process used for removing portions of the second photoresist layer preferably removes those portions of the second photoresist layer while leaving the first photoresist layer in place. As a result, the features of the third pattern exposed on the work surface have the high resolution of the features of the first pattern even though the third pattern was determined, in part, by the lower resolution second mask. The exposed portions of the work surface may then be processed using standard techniques.

In accordance with the invention, the first mask is one of the standard masks used in the formation of the structured ASIC while the second mask is one of the custom masks. As a result, while the first mask is a high resolution mask, its NRE costs can be spread over a large number of devices thereby reducing the cost of the mask per device made. And while the second mask is a custom mask designed only for a specific device, it need not be as high a resolution mask as the first mask and, in some cases, can be quite inexpensive.

In a particular application of applicants' invention the first mask can be used to expose the work surface at all those locations where connections could be made by a metallization layer or an array of vias and the second mask is used to expose only those locations where connections are required in a specific device.

In alternative embodiments of the invention, one or more hard masks may be used in place of one or more layers of photoresist.

As is known in the art, both positive and negative photoresists are available. Positive photoresists become more soluble in developer solution as a result of exposure to actinic radiation while negative photoresists become less soluble as a result of exposure to actinic radiation. Whichever type of photoresist is used, an exposure pattern is formed in the photoresist, and using well known methods, the more soluble portions of the photoresist layer are removed. The use of a negative photoresist has the added advantage that both exposure steps may be performed successively in the same layer of photoresist, thereby eliminating the need to apply a second layer of photoresist. In such a case the two exposures are advantageously performed using different radiation frequencies, with the high resolution exposure being performed at the higher frequency.

### BRIEF DESCRIPTION OF THE DRAWINGS

These and other objects and advantages of the present invention will be more readily apparent from the following Detailed Description in which:

FIG. 1 depicts a series of steps in processing a layer of metallization in the prior art;

FIGS. 2A and 2B depict a series of steps in an illustrative embodiment of the invention;

FIGS. 3A and 3B depict first and second masks used in the practice of the invention;

FIGS. 4A and 4B depict a series of steps in a second illustrative embodiment of the invention; and

FIGS. 5A and 5B depict a series of steps in a third illustrative embodiment of the invention.

### DETAILED DESCRIPTION

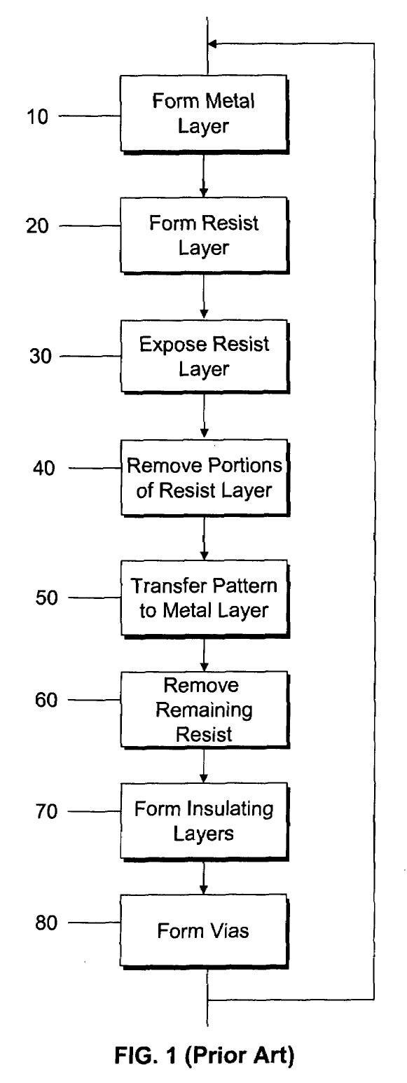

As is known in the art, several layers of metallization are formed one on top of the other on the surface of a semiconductor substrate. Patterns are formed in the layers of metallization using standard photolithographic steps so as to define conductive paths that interconnect the circuits formed in the underlying substrate. The general sequence for forming and processing one layer of aluminum metallization is shown in FIG. 1. Further details may be found in numerous texts on semiconductor processing such as S. A. Campbell, The Science and Engineering of Microelectronic Fabrication, Ch. 7 (Oxford, 2d ed. 2001) and J. D. Plummer et al., Silicon VLSI Technology, Ch. 5 (Prentice Hall, 2000).

As shown in FIG. 1, at step 10, a layer of metal is formed on the underlying surface. A uniform layer of photoresist is then formed on the metal layer at step 20. At step 30, the photoresist is exposed to actinic radiation in a pattern having features defined by a mask. Following the exposure step, portions of the photoresist are selectively removed at step 40 so as to expose portions of the underlying metal layer. As is known in the art, different types of photoresist are available, negative photoresists become less soluble in developer solution as a result of exposure to actinic radiation and positive photoresists become more soluble. Whichever type of photoresist is used, an exposure pattern is formed in the photoresist; and using well known methods the more soluble portions of the photoresist layer are removed. As a result, either the negative or the positive of this pattern is removed from the photoresist layer to expose the metal layer below. The exposed portions of the metal layer are then removed at step 50, thereby transferring the pattern from the photoresist to the metal layer. At step 60, the photoresist is removed leaving the pattern defined in the metal layer; and at step 70 an insulating layer is formed on the patterned metal layer. At step 80, vias are formed at selected places in the insulating layer to provide electrical connections to the patterned metal layer. At this point, another metal layer can be formed on top of the insulating layer using the steps just described.

In forming a structured ASIC, this process is repeated several times using standard (i.e., non-custom) masks to define the metallization layers that provide logic and hard functions such as memory, PLLs, clock and power bussing. The structured ASIC is completed using a few high resolution custom masks to define the critical metal layers.

As is known in the art, advanced technology nodes use copper metallization created by a damascene process, instead of aluminum metallization. The photolithographic process used in forming copper metallization is similar to that used in forming aluminum metallization; but in the damascene process, the work surface is a dielectric layer into which the mask pattern is transferred as a trench or a via that is subsequently filled with copper by electroplating.

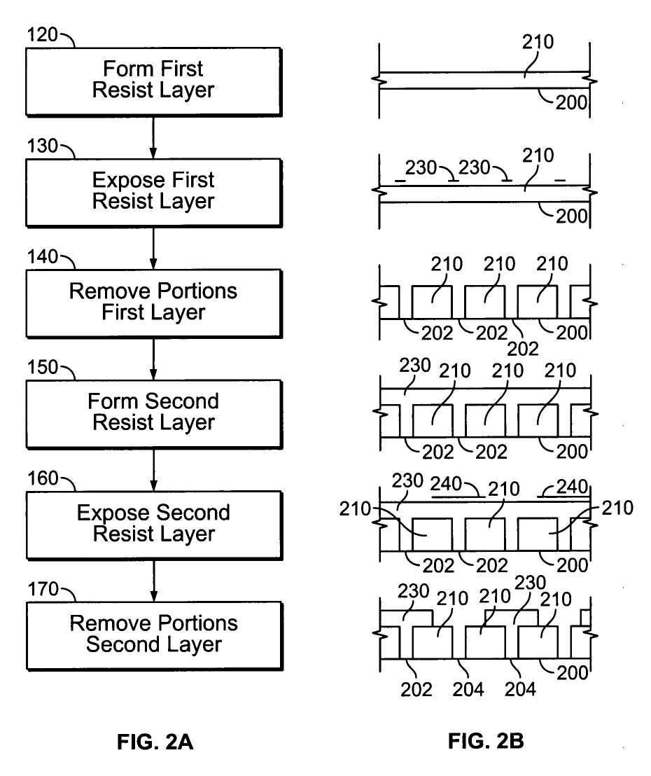

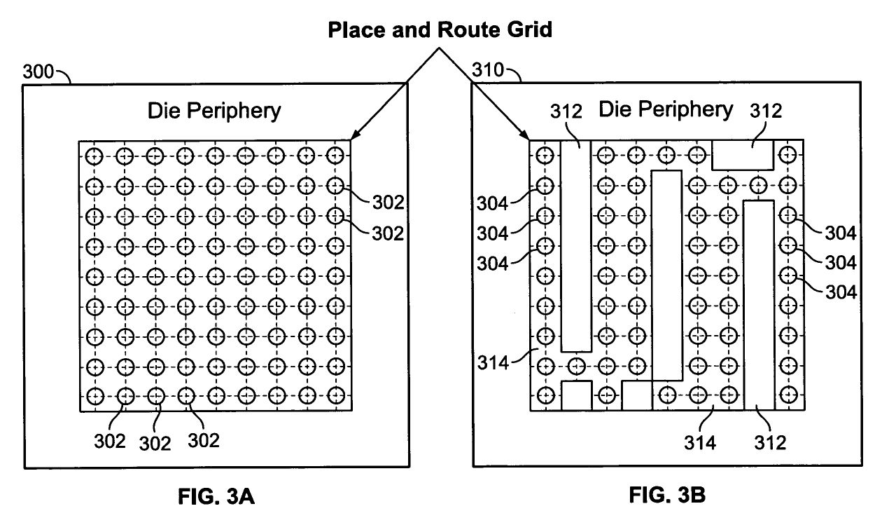

The present invention alters the conventional sequence of processing steps in the formation of one or more layers of metallization. FIG. 2A is a flowchart depicting the steps of an illustrative embodiment. FIG. 2B is a series of sketches alongside the steps of FIG. 2A that depict the processing referred to in the steps. At step 120, a first layer of photoresist 210 is formed on a work surface 200 such as a layer of metallization or dielectric. At step 130, the photoresist is then exposed to actinic radiation in a pattern having features defined by a first mask such as mask 300 shown in FIG. 3A. As shown in FIG. 3A, the mask is an extremely high resolution mask and the features defined by the mask are in a regular array extending across the entire region of the photoresist where structures are to be formed. Thus, mask 300 is a standard or non-custom mask. Elements of the radiation pattern formed on the photoresist are represented as dashes 220 in FIG. 2B. It will be noted, however, that the radiation preferably is in a high frequency region, invisible to the naked eye; and the mask that forms the pattern of dashes 220 is transparent to such radiation in the region of the dashes and is opaque everywhere else.

Following the exposure step, portions of the photoresist are selectively removed at step 140 so as to expose portions 202 of the underlying work surface 200. As is known in the art, both positive and negative types of photoresist are available although FIG. 2B illustrates the use of positive photoresists and positive masks. Whichever type of photoresist is used, an exposure pattern is formed in the photoresist, and using well known methods the more soluble portions of the photoresist layer are removed. As a result, either the positive or negative of this pattern is removed from the photoresist layer to expose a first, high resolution pattern on the work surface below. The remaining portions of the photoresist layer 210 are then hard baked so that they will not be affected by subsequent processing steps.

A second layer of photoresist 230 is then formed at step 150 on the first layer of photoresist 210 and on the exposed pattern 202 on the work surface. At step 160 the second layer of photoresist is then exposed to actinic radiation in a second pattern having features defined by a second mask such as mask 310 shown in FIG. 3B. Preferably, the second mask has a lower resolution than the first mask and as a result is considerably less expensive than the first mask even though mask 310 is a custom mask. Advantageously, the lower resolution exposure of step 160 is also made at a lower frequency than the high radiation exposure of step 130 using less expensive exposure equipment. The features defined by the second mask are aligned with the features defined by the first mask. Elements of the radiation pattern formed on the photoresist are represented by dashes 240 in FIG. 2B. Again, the radiation is typically invisible; and the mask is transparent to such radiation in the region of the dashes 240 and is opaque everywhere else.

Following the exposure step, portions of the second layer of photoresist are selectively removed at step 170 so as to expose portions 204 of the underlying work surface. Again, a positive or a negative photoresist can be used, although FIG. 2B illustrates the use of positive photoresists and positive masks. As shown in the bottom sketch of FIG. 2B, the portions of photoresist removed from the second layer are aligned with the regions of the first photoresist layer from which photoresist was removed in step 140 so that the removal of portions of the second photoresist layer exposes a third pattern 204 on the work surface that is a subset of the first pattern 202 previously exposed on the work surface. In logical terms, the third pattern is the logical AND of the first and second radiation patterns.

Further, the process used for removing portions of the second photoresist layer preferably removes those portions of the second photoresist layer while leaving the first photoresist layer in place. As a result, the features of the third pattern exposed on the work surface have the high resolution of the features of the first pattern even though the third pattern was determined, in part, by the lower resolution second mask. The exposed portions of the work surface may then be processed using standard lithographic processing techniques. For example, if the work surface is a layer of metallization, portions of the metallization may be removed to define connection patterns; or if the work surface is a dielectric, portions of the dielectric may be removed prior to electroplating copper in the removed portions.

FIGS. 3A and 3B illustrate masks 300 and 310 and their relationship to the pattern being formed on work surface 200. Please note that features defined by the masks in the die periphery region are not shown for simplicity's sake. Mask 300 illustratively is a high-grade optical proximity correction (OPC) mask and/or phase shift mask (PSM) that exposes on photoresist layer 210 a regular array of circular regions through an array of transparent circular apertures 302. All other regions of mask 300 are opaque at the frequency of radiation used during the exposure step. Photoresist layer 210 is then removed in these circular regions to expose circular regions 202 on work surface 200. Mask 310 illustratively is a low-grade binary mask having opaque regions 312 and transparent regions 314 and exposes on photoresist layer 230 regions that are images of transparent regions 314. The exposed regions on photoresist layer 230 are aligned with some 304 of the previously exposed circular regions as represented in FIG. 3B. As a result, when the exposed regions on photoresist layer 230 are removed at step 170 only some 204 of the previously exposed circular regions on the work surface are again exposed. These regions may then be subject to further processing, for example, to form vias.

For example, the masks of FIGS. 3A and 3B can be used to form the interconnection and vias in Altera Corporation's Hardcopy™ structured ASICs. In such an application, mask 300 which illustratively is a high-grade optical proximity correction (OPC) mask and/or phase shift mask (PSM) is used to form a pattern on the work surface that can be used to make every connection that might be made in that layer of work surface in the structured ASIC. Mask 310 which illustratively is a low-grade binary mask is then used to form a pattern on the work surface that makes only those connections that are required in that layer of work surface in the specific structured ASIC that is desired.

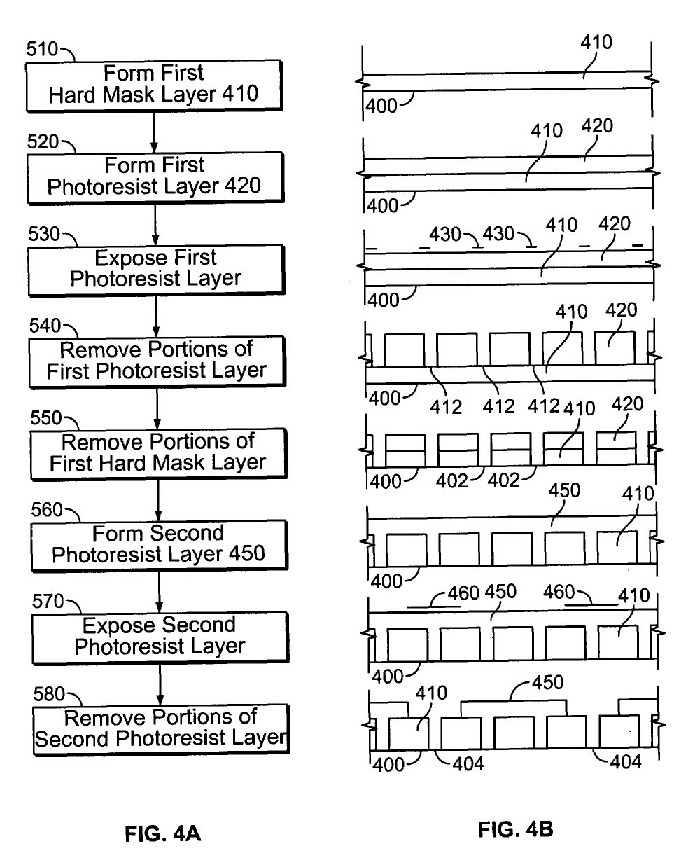

In an alternative process for practicing the invention, a hard mask may be used instead of a layer of photoresist. The hard mask is a layer of material such as silicon nitride or silicon carbide. FIG. 4A is a flowchart depicting the steps of one such alternative embodiment. FIG. 4B is a series of sketches alongside the steps of FIG. 4A that depict the processing referred to in the steps. At step 510, a hard mask layer 410 is formed on a work surface 400 such as a layer of metallization or dielectric. At step 520, a first layer of photoresist 420 is formed on hard mask layer 410. At step 530, the photoresist is then exposed to actinic radiation in a pattern having features defined by a first mask such as mask 300 shown in FIG. 3A. As shown in FIG. 3A, the mask is an extremely high resolution mask and the features defined by the mask are in a regular array extending across the entire region of the photoresist where structures are to be formed. Thus, mask 300 is a standard or non-custom mask. Elements of the radiation pattern formed on the photoresist are represented as dashes 430 in FIG. 4B. It will be noted, however, that the radiation preferably is in a high frequency region, invisible to the naked eye; and the mask that forms the pattern of dashes 430 is transparent to such radiation in the region of the dashes and is opaque everywhere else.

Following the exposure step, portions of the photoresist are selectively removed at step 540 so as to expose portions 412 of the underlying hard mask layer 410. As is known in the art, both positive and negative photoresists are available, although FIG. 4B illustrates the use of positive photoresists and positive masks. Whichever type of photoresist is used, an exposure pattern is formed in the photoresist, and using well known methods the more soluble portions of the photoresist layer are removed. As a result, either the positive or negative of this pattern is removed from the photoresist layer to expose a first, high resolution pattern on the work surface below. At step 550, the exposed portions of hard mask layer are removed so as to expose portions 402 of the underlying work surface 400. Illustratively, this removal is accomplished by an etching process.

A second layer of photoresist 450 is then formed at step 560 on the exposed portions of the work surface 400 and the remaining portions of hard mask layer 410. At step 570 the second layer of photoresist is then exposed to actinic radiation in a second pattern having features defined by a second mask such as mask 310 shown in FIG. 3B. Preferably, the second mask has a lower resolution than the first mask and as a result is considerably less expensive than the first mask even though mask 310 is a custom mask. Advantageously, the lower resolution exposure of step 570 is also made at a lower frequency than the high resolution exposure of step 530 using less expensive exposure equipment. The features defined by the second mask are aligned with the features defined by the first mask. Elements of the radiation pattern formed on the photoresist are represented by dashes 460 in FIG. 4B. Again, the radiation is typically invisible; and the mask is transparent to the radiation of the region of the dashes 460 and is opaque everywhere else.

Following the exposure step, portions of the second layer of photoresist are selectively removed at step 580 so as to expose portions 404 of the work surface. Again, a positive or a negative photoresist can be used, although FIG. 4B illustrates the use of positive photoresists and positive masks. As shown in FIG. 4B, the portions of photoresist removed from the second layer are aligned with the regions of the first hard mask layer that were removed in step 550 so that the exposed portions 404 form a third pattern on the work surface that is a subset of the first pattern 402 previously exposed on the work surface.

As a result, the features of the third pattern exposed on the work surface have the high resolution of the features of the first pattern even though the third pattern was determined, in part, by the lower resolution second mask. The third portions of the work surface may then be processed using standard lithographic processing techniques.

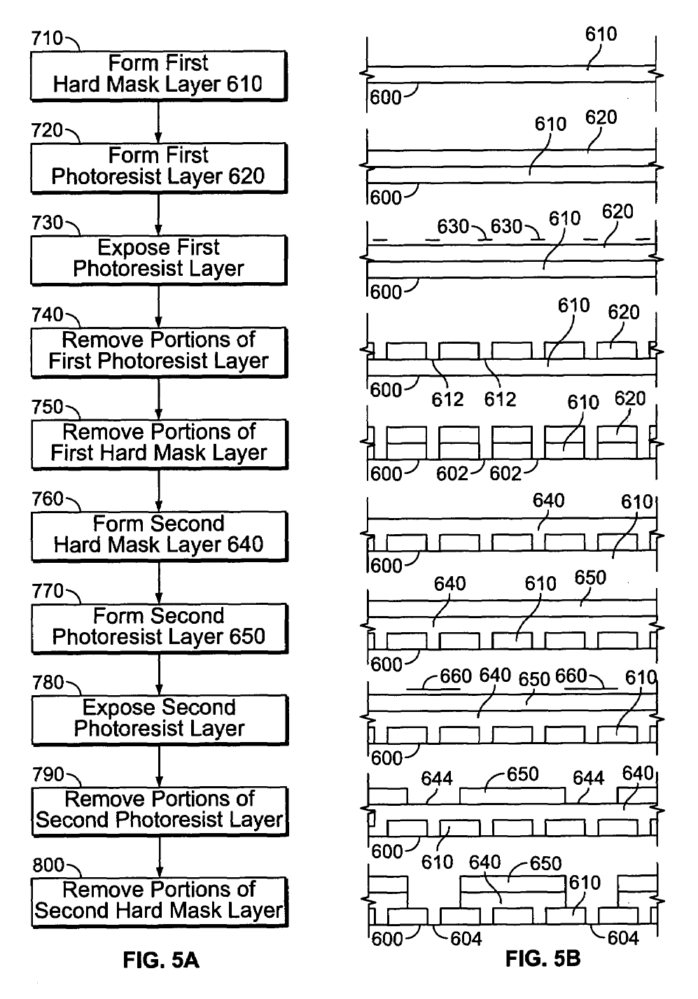

Alternatively, a dual set of hard masks may be used. FIG. 5A is a flowchart depicting the steps of this alternative embodiment. FIG. 5B is a series of sketches alongside the steps of FIG. 5A that depict the processing referred to in the steps. At step 710, a first hard mask layer 610 is formed on a work surface 600 such as a layer of metallization or dielectric. At step 720, a first layer of photoresist 620 is formed on hard mask layer 610. At step 730, the photoresist is then exposed to actinic radiation in a pattern having features defined by a first mask such as mask 300 shown in FIG. 3A. As shown in FIG. 3A, the mask is an extremely high resolution mask and the features defined by the mask are in a regular array extending across the entire region of the photoresist where structures are to be formed. Thus, mask 300 is a standard or non-custom mask. Elements of the radiation pattern formed on the photoresist are represented as dashes 630 in FIG. 5B. It will be noted, however, that the radiation preferably is in a high frequency region, invisible to the naked eye; and the mask that forms the pattern of dashes 630 is transparent to such radiation in the region of the dashes and opaque everywhere else.

Following the exposure step, portions of the photoresist are selectively removed at step 740 so as to expose portions 612 of the underlying hard mask layer 610. As is known in the art, both positive and negative photoresists are available, although FIG. 5B illustrates the use of positive photoresists and positive masks. Whichever type of photoresist is used, an exposure pattern is formed in the photoresist, and using well known methods the more soluble portions of the photoresist layer are removed. As a result, either the positive or negative of this pattern is removed from the photoresist layer to expose a first, high resolution pattern on the work surface below. At step 750, the exposed portions of hard mask layer are removed so as to expose portions 602 of the underlying work surface 600. Illustratively, this removal is accomplished by an etching process.

At step 760 a second hard mask layer 640 is formed on the exposed portions of work surface 600 and the remaining portions of the first hard mask layer. The second hard mask layer is sufficiently different from the first hard mask layer that portions of the second hard mask layer can be removed by a process applied to both layers without significant removal of the first layer. Typically, the two hard mask layers are different materials.

A second layer of photoresist 650 is then formed at step 770 on the second hard mask layer 640. At step 780 the second layer of photoresist is then exposed to actinic radiation in a second pattern having features defined by a second mask such as mask 310 shown in FIG. 3B. Preferably, the second mask has a lower resolution than the first mask and as a result is considerably less expensive than the first mask even though mask 310 is a custom mask. The features defined by the second mask are aligned with the features defined by the first mask. Elements of the radiation pattern formed on the photoresist are represented by dashes 660 in FIG. 5B. Again, the radiation is typically invisible; and the mask is transparent to such radiation in the region of dashes 660 and is opaque everywhere else.

Following the exposure step, portions of the second layer of photoresist are selectively removed at step 790 so as to expose portions 644 of the underlying second hard mask layer 640. Again, a positive or a negative photoresist can be used. As shown in FIG. 5B, the portions of photoresist removed from the second layer are aligned with the regions of the first hard mask layer that were removed in step 750.

At step 800, the exposed portions of the second hard mask layer are removed as to expose a third pattern 604 on the work surface that is a subset of the first pattern 602 previously exposed on the work surface. Illustratively, this removal is accomplished by an etching process that removes those portions of the second hard mask layer while leaving the first hard mask layer in place. As a result, the features of the third pattern exposed on the work surface have the high resolution of the features of the first pattern even though the third pattern was determined, in part, by the lower resolution second mask. The third portions of the work surface may then be processed using standard lithographic processing techniques.

In still another embodiment of the invention, a single layer of negative photoresist is used. The practice of the invention is similar to that described in conjunction with FIGS. 2A and 2B except that the steps are carried out on a single layer of photoresist. In this process, a layer of photoresist is first formed on a work surface such as a layer of metallization or dielectric. The photoresist is then exposed to actinic radiation at a first wavelength to which the photoresist is sensitive in a pattern having features defined by a first mask such as the complement of mask 300 shown in FIG. 3A. As shown in FIG. 3A, the mask is an extremely high resolution mask and the features defined by the mask are in a regular array extending across the entire region of the photoresist where structures are to be formed. Thus, the mask is a standard or non-custom mask.

The photoresist is then exposed to actinic radiation in a second pattern having features defined by a second mask such as the complement of mask 310 shown in FIG. 3B. Preferably, the second mask has a lower resolution than the first mask and as a result is considerably less expensive than the first mask even though mask 310 is a custom mask. Advantageously, the lower resolution exposure is also made at a lower frequency than the high resolution exposure using less expensive exposure equipment. The features defined by the second mask are aligned with the features defined by the first mask.

Following the two exposure steps, the portions of the photoresist that were not exposed during either exposure step are selectively removed so as to expose portions of the underlying work surface. As a result, the areas of photoresist that were not exposed in either or both exposure steps are removed from the photoresist layer to expose a third, high resolution pattern on the work surface below. In logical terms, the third pattern is the complement of the logical OR of the first and second radiation patterns; and in the case where the first and second radiation patterns are the complements of masks 300 and 310, respectively, the third pattern is the logical AND of the first and second radiation patterns of FIG. 2B.

While the invention has been described in terms of specific embodiments, numerous variations of the invention may be practiced. For example, a wide variety of photoresists and a wide variety of hard masks (such as different hard mask materials or different numbers of masks) may be used in the practice of the invention. Where two layers of photoresist are used, care must be taken in selecting the materials to ensure that the process for removing portions of the upper layer does not affect the portion of the lower layer that remains in place.

What is claimed is:

1. A double exposure photolithographic method comprising the steps of:
forming a first layer of photoresist on a work surface;
exposing the first layer of photoresist to actinic radiation in a first pattern having features defined by a first photolithographic mask;
removing portions of the first layer of photoresist defined by the actinic radiation so as to expose a first pattern on the work surface;
forming a second layer of photoresist on the first layer of photoresist and the exposed pattern on the work surface;
exposing the second layer of photoresist to actinic radiation in a second pattern having features defined by a second photolithographic mask and aligned with the first pattern exposed on the work surface;
removing portions of the second layer of photoresist defined by the actinic radiation so as to expose a third pattern on the work surface; and
transferring the third pattern to the work surface wherein the first photolithographic mask is a non-custom mask used in forming a structured application specific integrated circuit (ASIC) and the second photolithographic mask is a custom mask used in forming an ASIC.

2. The photolithographic method of claim 1 wherein the first photolithographic mask has a higher resolution than the second photolithographic mask.

3. The photolithographic method of claim 1 wherein the first photolithographic mask is a phase shift mask or an optical proximity correction mask.

4. The photolithographic method of claim 1 wherein the second photolithographic mask is a binary mask.

5. The method of claim 1 wherein the work surface is a layer of metallization.

6. The method of claim 1 wherein the work surface is a dielectric layer and the step of transferring the third pattern to the work surface comprises the step of removing portions of the work surface defined by the third pattern.

7. The method of claim 1 further comprising the step of hard baking the second layer of photoresist.

8. A double exposure photolithographic method comprising the steps of:
forming a first hard mask layer on a work surface;
forming a first layer of photoresist on the first hard mask layer;
exposing the first layer of photoresist to actinic radiation in a first pattern having features defined by a first photolithographic mask;
removing portions of the first layer of photoresist defined by the actinic radiation so as to expose a first pattern on the first hard mask layer;
removing portions of the first hard mask layer to expose the first pattern on the work surface;
forming a second layer of photoresist on remaining portions of the first hard mask layer and exposed portions of the work surface;
exposing the second layer of photoresist to actinic radiation in a second pattern having features defined by a second photolithographic mask and aligned with the first pattern exposed on the work surface;
removing portions of the second layer of photoresist defined by the actinic radiation so as to expose a third pattern on the work surface; and
transferring the third pattern to the work surface.

9. The photolithographic method of claim 8 wherein the first photolithographic mask has a higher resolution than the second photolithographic mask.

10. The photolithographic method of claim 8 wherein the first photolithographic mask is a phase shift mask or an optical proximity correction mask.

11. The photolithographic method of claim 8 wherein the second photolithographic mask is a binary mask.

12. The method of claim 8 wherein the first photolithographic mask is a non-custom mask used in forming a structured application specific integrated circuit (ASIC) and the second photolithographic mask is a custom mask used in forming an ASIC.

13. The method of claim 8 wherein the work surface is a layer of metallization.

14. The method of claim 8 wherein the work surface is a dielectric layer and the step of transferring the third pattern to the work surface comprises the step of removing portions of the work surface defined by the third pattern.

15. A method for forming a structured application specific integrated circuit (ASIC) comprising the steps of:
(a) forming a first layer of photoresist on a first work surface;
(b) exposing the first layer of photoresist to actinic radiation in a first pattern having features defined by a first photolithographic mask;
(c) removing portions of the first layer of photoresist defined by the actinic radiation so as to expose a first pattern on the first work surface;
(d) transferring the first pattern to the first work surface;
(e) forming a second work surface on the first work surface;
(f) forming a second layer of photoresist on the second work surface;
(g) exposing the second layer of photoresist to actinic radiation in a second pattern having features defined by a second photolithographic mask;
(h) removing portions of the second layer of photoresist defined by the actinic radiation so as to expose a second pattern on the second work surface;
(i) forming a third layer of photoresist on the second layer of photoresist and the exposed pattern on the second work surface;
(j) exposing the third layer of photoresist to actinic radiation in a third pattern having features defined by a third photolithographic mask and aligned with the second pattern exposed on the second work surface;
(k) removing portions of the third layer of photoresist defined by the actinic radiation so as to expose a fourth pattern on the second work surface; and
(l) transferring the fourth pattern to the second work surface.

16. The method of claim 15 wherein the masks used in steps (b) and (f) are non-custom masks and the mask used in step (i) is a custom mask.

17. The method of claim 15 wherein the second photolithographic mask has a higher resolution than the third photolithographic mask.

18. The method of claim 15 wherein the third photolithographic mask is a binary mask.

19. The method of claim 15 wherein the second photolithographic mask is a phase shift mask or an optical proximity correction mask.

20. The method of claim 15 wherein steps (a) through (e) are repeated for at least one additional work surface formed above the first work surface.

21. The method of claim 20 wherein the photolithographic mask used in each step (b) and in step (f) is a non-custom mask.

22. A double exposure photolithographic method comprising the steps of:
forming a first hard mask layer on a work surface;
forming a first layer of photoresist on the first hard mask layer;
exposing the first layer of photoresist to actinic radiation in a first pattern having features defined by a first photolithographic mask;
removing portions of the first layer of photoresist defined by the actinic radiation so as to expose a first pattern on the first hard mask layer;
removing portions of the first hard mask layer to expose the first pattern on the work surface;
forming a second hard mask layer on remaining portions of the first hard mask layer and exposed portions of the work surface;
forming a second layer of photoresist on the second hard mask layer;
exposing the second layer of photoresist to actinic radiation in a second pattern having features defined by a second photolithographic mask and aligned with the first pattern exposed on the work surface;
removing portions of the second layer of photoresist defined by the actinic radiation so as to expose a second pattern on the second hard mask layer;
removing portions of the second hard mask layer to expose a third pattern on the work surface; and
transferring the third pattern to the work surface.

23. The photolithographic method of claim 22 wherein the first photolithographic mask has a higher resolution than the second photolithographic mask.

24. The photolithographic method of claim 22 wherein the first photolithographic mask is a phase shift mask or an optical proximity correction mask.

25. The photolithographic method of claim 22 wherein the second photolithographic mask is a binary mask.

26. The method of claim 22 wherein the first photolithographic mask is a non-custom mask used in forming a structured application specific integrated circuit (ASIC) and the second photolithographic mask is a custom mask used in forming an ASIC.

27. The method of claim 22 wherein the work surface is a layer of metallization.

28. The method of claim 22 wherein the work surface is a dielectric layer and the step of transferring the third pattern to the work surface comprises the step of removing portions of the work surface defined by the third pattern.

29. A set of photolithographic masks for use in fabricating a semiconductor integrated circuit comprising:
a plurality of non-custom masks at least one of which is a high resolution mask; and
at least one custom mask having a resolution less than that of the high resolution mask.

30. The set of photolithographic masks of claim 29 wherein the custom mask is a binary mask.

31. The set of photolithographic masks of claim 29 wherein the high resolution mask is a phase shift mask or an optical proximity correction mask.

32. A double exposure photolithographic method comprising the steps of:
forming a layer of negative photoresist on a work surface;
exposing the layer of photoresist to actinic radiation in a first pattern having features defined by a first photolithographic mask;
exposing the layer of photoresist to actinic radiation in a second pattern having features defined by a second photolithographic mask and aligned with the first pattern;
removing portions of the layer of photoresist not exposed by the actinic radiation in the first or second patterns so as to expose a third pattern on the work surface; and
transferring the third pattern to the work surface wherein the first photolithographic mask is a non-custom mask used in forming a structured application specific integrated circuit (ASIC) and the second photolithographic mask is a custom mask used in forming an ASIC.
